(19) United States
(12) Patent Application Publication
(10) Pub. No.: US 2026/0182088 A1
(43) Pub. Date: Jun. 25, 2026

(54) NEAR-ULTRAVIOLET MICROLED ARRAY WITH NOVEL QUANTUM WELL DESIGN

(71) Applicant: LUMILEDS LLC, San Jose, CA (US)

(72) Inventor: Robert ARMITAGE, Cupertino, CA (US)

(73) Assignee: LUMILEDS LLC, San Jose, CA (US)

(21) Appl. No.: 18/999,961

(22) Filed: Dec. 23, 2024

(51) Int. Cl. H10H 20/812; H10H 20/821; H10H 20/825; H10H 29/14; H10H 29/851

(52) U.S. Cl. CPC H10H 20/812; H10H 20/821; H10H 20/825; H10H 29/142; H10H 29/8511

(57) ABSTRACT

A new design for a near-UV emitting quantum well structure exhibits a small electron-hole wavefunction overlap. The small electron-hole overlap is beneficial for near UV-microLEDs because small overlap results in a high carrier density even at low current densities. Due to the higher carrier density, non-radiative recombination centers are saturated at relatively low current density in the newly disclosed design. The new design is therefore more robust against non-recombination losses at both intrinsic and surface defects, and capable of higher efficiency than conventional designs at low current densities.

### FIELD OF THE INVENTION

The invention relates generally to near-ultraviolet emitting microLEDs and microLED arrays.

### BACKGROUND

Inorganic semiconductor light emitting diodes and laser diodes (collectively referred to herein as “LEDs”) are among the most efficient light sources currently available. The emission spectrum of an LED typically exhibits a single narrow peak at a wavelength determined by the structure of the device and by the composition of the semiconductor materials from which it is constructed. By suitable choice of device structure and material system, LEDs may be designed to operate at ultraviolet, visible, or infrared wavelengths. LEDs may be combined with one or more wavelength converting materials (e.g., semiconductor nanocrystal “quantum dots”) that absorb light emitted by the LED and in response emit light of a longer wavelength. Such devices comprising wavelength converting material may be referred to herein as wavelength converted LEDs. Devices lacking such wavelength converting material may be referred to herein as direct emitting LEDs.

Direct emitting LEDs and wavelength converted LEDs may be used to create different types of displays including, for example, augmented-reality (AR) displays, virtual-reality (VR) displays, and mixed-reality (MR) displays.

LEDs having largest lateral dimensions (i.e., parallel to the semiconductor layers of the active region) of about 50 microns or less are typically referred to as microLEDs. MicroLED arrays are of commercial interest for fabricating high-resolution full-color displays with high brightness and low power consumption. Typically, direct emitting LEDs of different colors are grown using different semiconductor materials on different substrate wafer materials (e.g. sapphire for blue/green but GaAs for red). The approach of transferring individual red, green, and blue direct emitting microLEDs from separate wafers to a display backplane is technically feasible. However, for smaller pixel sizes the above approach becomes problematic in terms of yields, throughput, and manufacturing cost.

An alternative approach is to deposit quantum dot (QD) color-conversion materials over selected positions of an array of blue or near-ultraviolet (near-UV) microLEDs fabricated on a single wafer. QD deposition may be accomplished with low-cost methods such as inkjet printing. The advantages of using near-UV (instead of blue) microLEDs in this approach were discussed in an article by Mingwei Zhu et al. (Information Display, vol. 40, issue 3, p. 20-25, May/June 2024, https://sid.onlinelibrary.wiley.com/doi/epdf/10.1002/msid.1485). Briefly, using near-UV LEDs allows for 1) the repair of defective pixels with less redundancy and 2) the use of non-toxic QD materials which absorb strongly in near-UV but not in blue wavelengths. The latter advantage allows for the manufacture of displays which comply with Restriction of Hazardous Substances (RoHS) requirements applicable in the European market.

The main drawback of the approach discussed by Mingwei Zhu et al. is the relatively poor efficiency of near-UV LEDs at low current densities (compared to blue or green LEDs). The low-current efficiency further worsens in near-UV microLEDs with small pixel sizes due to additional non-radiative recombination losses via surface defects. Accordingly, there is a need for near-UV microLEDs with higher efficiencies specifically at lower current densities.

### SUMMARY

This specification discloses a new design of near-UV emitting quantum well structure that exhibits a small electron-hole wavefunction overlap. In the usual context of high-power LED applications, a small electron-hole overlap is not desirable because it decreases the maximum External Quantum Efficiency (EQE) and worsens the “droop” phenomenon (non-thermal efficiency decrease with increasing current due to Auger recombination at higher carrier densities). However, the inventor has recognized that small electron-hole overlap is beneficial for near UV-microLEDs because small overlap results in a high carrier density even at low current densities. Due to the higher carrier density, non-radiative recombination centers are saturated at relatively low current density in the newly disclosed design. The new design is therefore more robust against nonradiative-recombination losses at both intrinsic and surface defects, and capable of higher efficiency than conventional designs at low current densities.

In one embodiment, such a microLED comprises an n-type Alₓ₁Ga₁₋ₓ₁N region, 0≤x1≤0.6; a p-type Alₓ₂Ga₁₋ₓ₂N region, 0≤x2≤0.6; and an active region disposed between the n-type Alₓ₁Ga₁₋ₓ₁N region and the p-type Alₓ₂Ga₁₋ₓ₂N region. The active region comprises two or more Alₓ₃Ga₁₋ₓ₃N barrier layers, 0.10≤x3≤1.0, each Alₓ₃Ga₁₋ₓ₃N barrier layer having a thickness perpendicular to the layer of about 5.0 nm to about 20 nm; and one or more In_{y}Ga_{1-y}N quantum well layers, 0.0≤y<0.05, each In_{y}Ga_{1-y}N quantum well layer having a thickness of about 3.0 nm to about 6.0 nm and disposed between a pair of adjacent Alₓ₃Ga₁₋ₓ₃N barrier layers.

The active region of the microLED may have a largest dimension parallel to the barrier layers and the quantum well layers of, for example, less than or equal to about 50 microns, less than or equal to about 20 microns, or less than or equal to about 5 microns. Typically, this dimension is greater than or equal to about 1 micron, but this dimension may be less than or equal to about 1 micron if suitable.

The microLED may be configured to emit light having a peak wavelength of, for example, about 375 nm to about 395 nm, for example about 385 nm, upon application of a forward bias across the active region.

In some variations, 0.10≤x3≤0.50.

In some variations, 0.0≤y≤0.02.

In some variations, the active region has a largest dimension of about less than or equal to about 20 microns parallel to the barrier layers and the quantum well layers, 0.10≤x3≤0.50, and 0.0≤y≤0.02. For example, in some variations x3=0.25, and y=0.0. In such variations the microLED may be configured to emit light having a peak wavelength of, for example, about 375 nm to about 395 nm, for example about 385 nm, upon application of a forward bias across the active region.

The microLED may comprise an n-type V-defect generating layer disposed between the n-type Alₓ₁Ga₁₋ₓ₁N region and the active region and generating V-defects in the active region. The n-type V-defect generating layer may be or comprise an n-type Alₓ₄Ga₁₋ₓ₄N layer, 0≤x4≤0.5. Alternatively or in addition the n-type V-defect generating layer may be or comprise a stack of one or more n-type Alₓ₅Ga₁₋ₓ₅N layers and one or more n-type In_{y2}Ga_{1-y2}N layers, 0≤x5≤0.15, 0.0≤y2≤0.85. Alternatively, in some variations 0≤x5≤0.5, and 0.0≤y2≤0.15. MicroLEDs comprising n-type V-defects may also comprise a p-type Aₓ₆Ga₁₋ₓ₆N planarization layer disposed between the active region and the p-type Alₓ₂Ga₁₋ₓ₂N region and filling V-defects in the active region, 0.10≤x6≤0.4. In some variations x6=0.10. In some variations of such microLEDs the active region has a largest dimension of less than or equal to about 20 microns parallel to the barrier layers and the quantum well layers, x3=0.25, y=0.0, and x6=0.10.

Any of the microLEDs summarized above may comprise quantum dots arranged and configured to absorb ultraviolet light emitted by the active region and in response emit visible light.

A monolithic array of microLEDs may comprise two or more of any of the microLEDs summarized above physically interconnected by a shared n-type Alₓ₁Ga₁₋ₓ₁N region. In such a monolithic array of microLEDs, each microLED may be configured to emit near ultraviolet light having a peak wavelength of, for example, about 375 nm to about 395 nm upon application of a forward bias across the microLED's active region. The monolithic array of microLEDs may comprise quantum dots arranged and configured to absorb ultraviolet light emitted by the active regions of the microLEDs and in response emit visible light. The quantum dots may comprise red-emitting, blue-emitting, and green-emitting quantum dots arranged with respect to the microLEDs to form red, blue, and green microLED pixel elements in the monolithic array.

These and other embodiments, features and advantages of the present invention will become more apparent to those skilled in the art when taken with reference to the following more detailed description of the invention in conjunction with the accompanying drawings that are first briefly described.

### BRIEF DESCRIPTION OF THE DRAWINGS

FIG. 1A shows the calculated 1D band structure for a GaN/3 nm thick In_{0.05}Ga_{0.95}/GaN quantum well structure.

FIG. 1B shows the calculated position dependence of the electron and hole wave functions for a GaN/3 nm thick In_{0.05}Ga_{0.95}/GaN quantum well structure.

FIG. 2A shows the calculated 1D band structure for a Al_{0.25}Ga_{0.75}N/3.5 nm thick GaN/Al_{0.25}Ga_{0.75}N quantum well structure.

FIG. 2B shows the calculated position dependence of the electron and hole wave functions for a Al_{0.25}Ga_{0.75}N/3.5 nm thick GaN/Al_{0.25}Ga_{0.75}N quantum well structure

FIG. 3 shows the estimated Internal Quantum Efficiency (IQE) as a function of driving current density for an Al_{0.25}Ga_{0.75}N/3.5 nm thick GaN/Al_{0.25}Ga_{0.75}N quantum well structure and for a GaN/3 nm thick In_{0.05}Ga_{0.95}/GaN quantum well structure.

FIG. 4 shows a schematic cross-section of an example near UV microLED according to the new designs disclosed herein.

FIG. 5 shows a schematic cross-section of an example near UV microLED as in FIG. 4 comprising a growth substrate.

FIG. 6 shows a schematic cross-section of an example near UV microLED as in FIG. 4 comprising an (optional) n-type V-defect generating layer.

FIG. 7 shows a schematic cross-section of an example wavelength converted microLED comprising a microLED structure as in FIG. 4, for example, and a layer of quantum dots disposed on a light emitting surface of the microLED structure.

FIG. 8 shows a schematic cross-section of a portion 800 of an example monolithic array of microLEDs.

FIG. 9 shows a schematic plan view of an example monolithic array of direct emitting microLEDs.

FIG. 10 shows a schematic plan view of an example monolithic array of wavelength (quantum dot) converted microLEDs.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the invention. The detailed description illustrates by way of example, not by way of limitation, the principles of the invention.

The inventor simulated the performance of near-UV emitting microLEDs having active regions comprising conventional quantum well structures in which 3 nm thick In_{0.05}Ga_{0.95} quantum well layers are sandwiched between GaN barrier layers for mesa sizes of 1 micron, 1.5 microns, 3 microns, 6 microns, 12 microns, 25 microns, and 50 microns. (The mesa is an etched structure that defines the largest lateral dimension of the active region). The emission wavelength for this structure is 385 nm when the devices are driven at 5 A/cm2. These devices showed a significant and debilitating decrease in EQE at current densities of 1 Amp/cm² (a current density of interest for microLED arrays) as the mesa size decreases, with EQE about 35% for a 50 micron mesa and about 3% for a 1 micron mesa. The low efficiency of such near-UV microLEDs at low current density hinders their adoption in existing display systems which have been designed to operate at a very small current per pixel (e.g., about 500 nA).

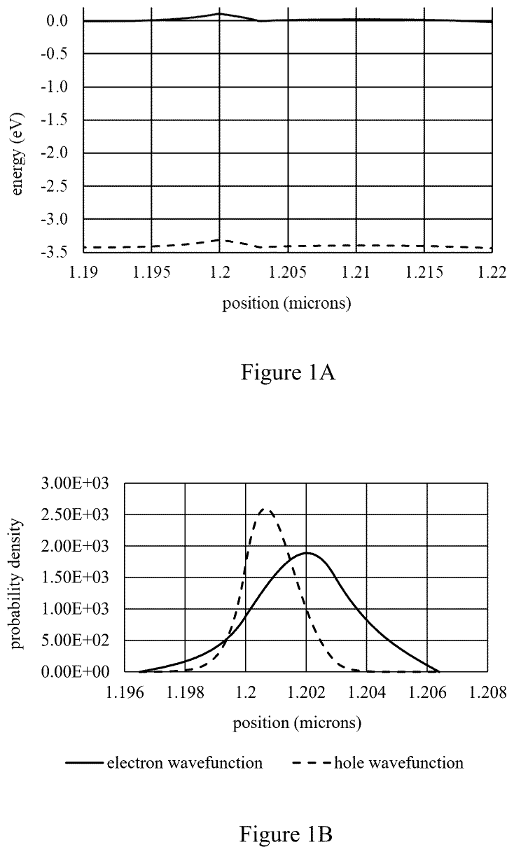

The decline of EQE with decreasing mesa sizes for the conventional GaN/3 nm thick In_{0.05}Ga_{0.95}/GaN quantum well structure is explained in part by the calculated 1D band structure (FIG. 1A) and the calculated resulting position dependence of the electron and hole wave functions (FIG. 1B). In FIG. 1A the solid line depicts the edge of the conduction band and the dashed line depicts the edge of the valence band. The electron and hole wavefunctions for this quantum well structure strongly overlap, which promotes both radiative and nonradiative recombination. The impact of nonradiative recombination at surface defects on EQE increases with smaller mesa size as a result of the increase of the surface-to-volume ratio of the mesa at smaller sizes.

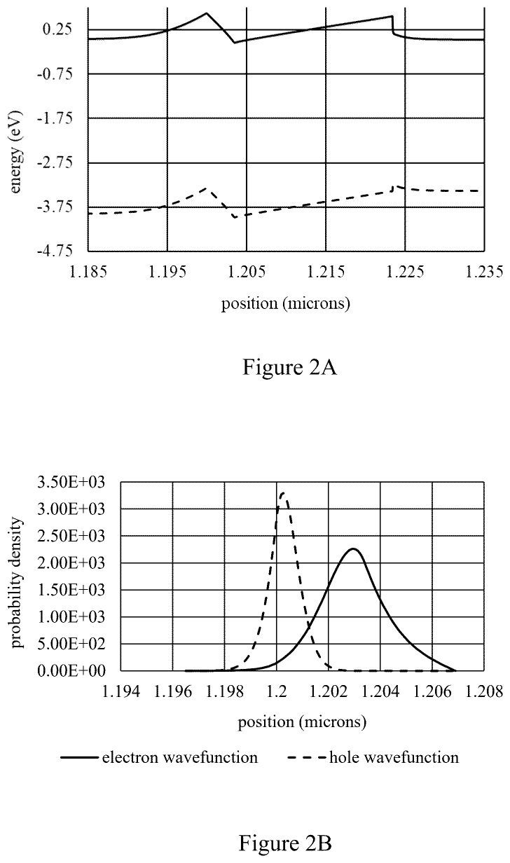

FIGS. 2A and 2B show, respectively, the calculated 1D band structure and the calculated resulting position dependence of the electron and hole wave functions for a Al_{0.25}Ga_{0.75}N/3.5 nm thick GaN/Al_{0.25}Ga_{0.75}N quantum well structure, which is an example of the new microLED quantum well designs disclosed herein. The emission wavelength for this structure is 385 nm when the devices are driven at 5 A/cm2. In FIG. 2A the solid line depicts the edge of the conduction band and the dashed line depicts the edge of the valence band. In this example quantum well structure the band offsets and polarization charges at the Al_{0.25}Ga_{0.75}N/GaN interfaces result in a significant separation of the electron and hole wave functions compared to that shown in FIG. 1B for the conventional GaN/3 nm thick In_{0.05}Ga_{0.95}/GaN quantum well structure.

As explained above, in operation of a microLED the small electron-hole overlap for the Al_{0.25}Ga_{0.75}N/3.5 nm thick GaN/Al_{0.25}Ga_{0.75}N quantum well structure results in a high carrier density even at low current densities, because it suppresses both radiative and nonradiative recombination. Due to the high carrier density, non-radiative recombination centers are saturated at relatively low current density and the device exhibits enhanced EQE.

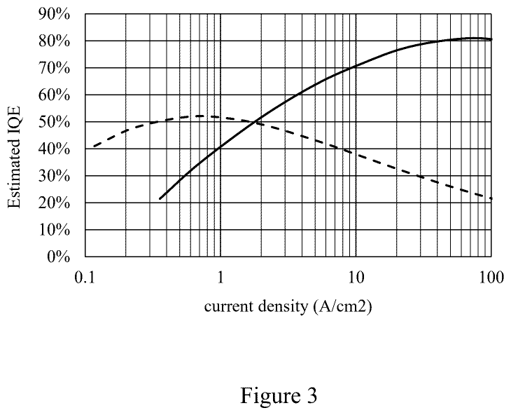

FIG. 3 shows the estimated Internal Quantum Efficiency (IQE) as a function of driving current density for the Al_{0.25}Ga_{0.75}N/3.5 nm thick GaN/Al_{0.25}Ga_{0.75}N quantum well structure (dashed line) and the GaN/3 nm thick In_{0.05}Ga_{0.95}/GaN quantum well structure (solid line). The Al_{0.25}Ga_{0.75}N/3.5 nm thick GaN/Al_{0.25}Ga_{0.75}N quantum well structure shows significantly better IQE at lower current densities.

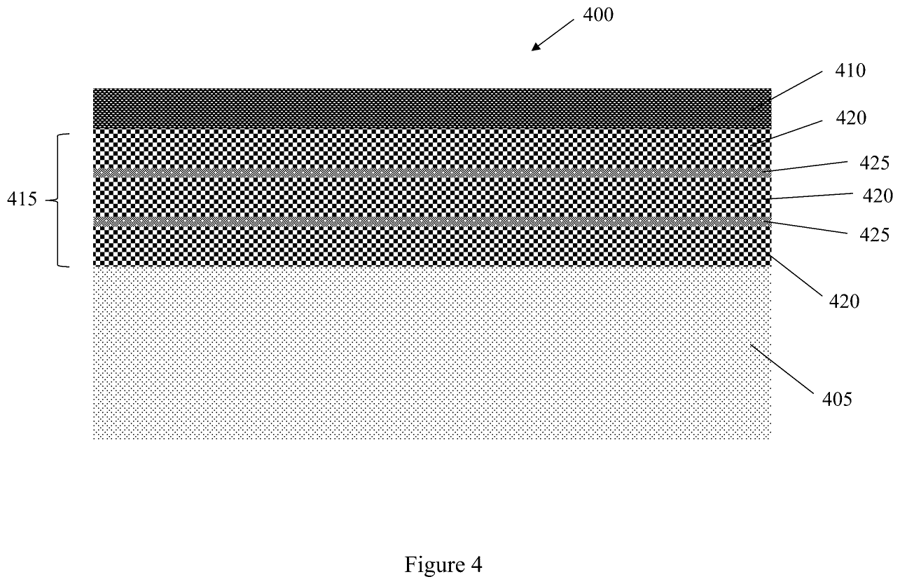

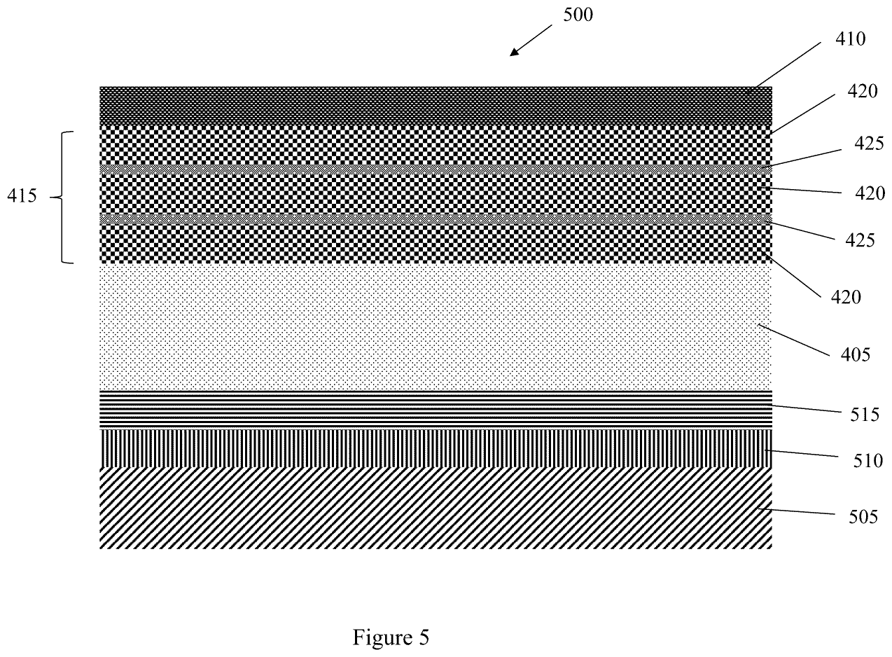

FIG. 4 shows a schematic cross-section of an example near UV microLED 400 according to the new designs disclosed herein. MicroLED 400 comprises an n-type Alₓ₁Ga₁₋ₓ₁N region (or layer) 405, a p-type Alₓ₂Ga₁₋ₓ₂N region 410, and an active region 415 disposed between the n-type Alₓ₁Ga₁₋ₓ₁N region and the p-type Alₓ₂Ga₁₋ₓ₂N region. The active region 415 comprises two or more Alₓ₃Ga₁₋ₓ₃N barrier layers 420, with each Alₓ₃Ga₁₋ₓ₃N barrier layer having a thickness perpendicular to the layer of about 5.0 nm to about 20 nm. The active region also comprises one or more In_{y}Ga_{1-y}N quantum well layers 425, with each In_{y}Ga_{1-y}N quantum well layer having a thickness of about 3.0 nm to about 6.0 nm and disposed between a pair of adjacent Alₓ₃Ga₁₋ₓ₃N barrier layers. Ranges for the subscripts defining the compositions of the materials in this structure are provided in the summary section above.

The threading dislocation density of n-type Alₓ₁Ga₁₋ₓ₁N region 405 is less than 5×10⁹ cm⁻² and preferably less than 5×10⁸ cm⁻². This region may have Si or Ge doping concentration in the range 1×10¹⁸ to 1×10²⁰ cm⁻³ to facilitate n-type ohmic contact formation and current spreading. Gradients in doping within the thickness of the region may exist. Typical region thickness is in the range 0.5-2 microns.

As noted in the summary section, in active region 415 the barrier layer 420 composition may be between about 10% and 100% Al, but below 50% Al is often sufficient. Generally, an Al composition of 10% or greater in the barrier layers provides sufficiently strong polarization fields to result in the desired (small) electron and hole wavefunction overlap in the well layers 425. The In_{y}Ga_{1-y}N quantum well layers may be GaN layers or dilute InGaN layers, where dilute InGaN refers to a composition of less than 5% In, preferably less than or equal to 2% In. The QW emission wavelength is typically around 385 nm but may vary somewhat with current density (see below for further discussion).

The p-type Alₓ₂Ga₁₋ₓ₂N region 410, which may comprise one or more layers, is typically Mg-doped. In the surface portion of region 410 (referring to the surface farther away from the active layers), the Al composition may be reduced and the Mg concentration increased to facilitate formation of a low resistance metal/semiconductor contact with an anode metal contact. The portion of region 410 in direct contact with the anode metal contact may for example comprise GaN:Mg with thickness between 5 and 30 nm and having a Mg concentration between 1×10²⁰ cm⁻³ and 5×10²⁰ cm⁻³.

FIG. 5 shows a schematic cross-section of an example near UV microLED 500 comprising growth substrate 505, according to the new designs disclosed herein. Substrate 505 is typically sapphire or silicon. A III-Nitride nucleation layer 510, typically GaN or AlN, is grown on substrate 505. One or more III-Nitride dislocation filtering/blocking layers 515, typically GaN, AlN, or an AlGaN alloy are grown on nucleation layer 510 at a higher temperature than used for growth of the nucleation layer. A sequence of one or more III-nitride and silicon nitride in-situ masking layers (not shown) may be further applied for the purpose of filtering/blocking threading dislocations. The microLED 400 structure shown in FIG. 4 is then grown.

A complete microLED structure comprises electrical contacts (not shown) by which in operation of the device a voltage may be applied across active region 415 to cause it to emit light. Such electrical contacts may, for example, be reflective and also function as mirrors or be transparent allowing transmission of light though the contact. The microLED may be configured such that in operation light is emitted from the device through a surface of the n-type region 405 or, alternatively, through a surface of the p-type region 410. The microLED may be removed from the growth substrate 505 if desired.

In one example configuration, a mirror is deposited on a surface of the p-type region 410 and light is emitted through n-type region 405. In such a configuration, if growth substrate 505 is silicon it is removed to allow transmission of light out of the device through the n-type region 405. If alternatively the substrate is (transparent) sapphire, it may be retained.

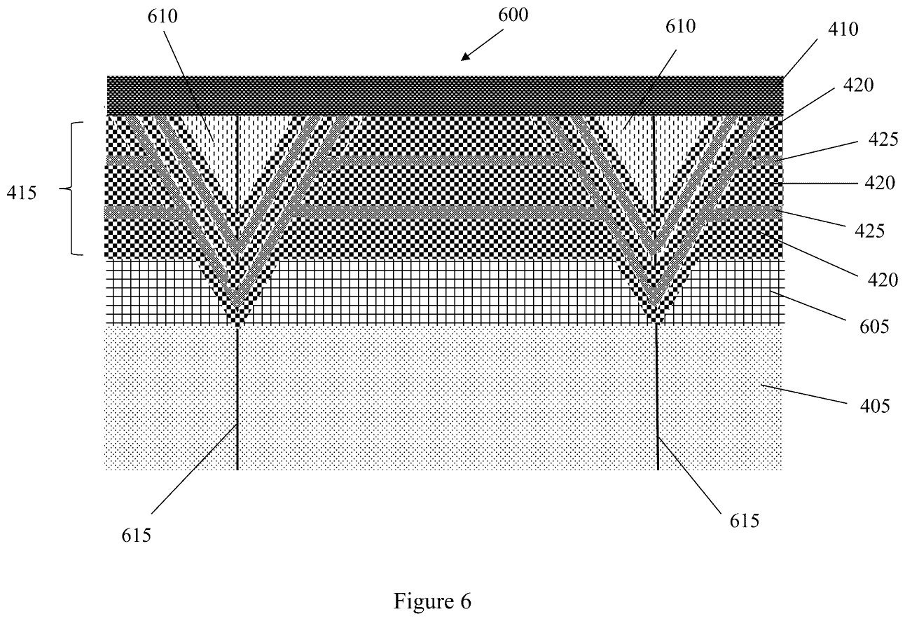

FIG. 6 shows a schematic cross-section of an example near UV microLED 600 comprising an (optional) n-type V-defect generating layer 605 disposed between the n-type Alₓ₁Ga₁₋ₓ₁N region 405 and the active region 415 and generating V-defects in the active region. The n-type V-defect generating layer may be or comprise a low temperature n-type (Si doped) Alₓ₄Ga₁₋ₓ₄N layer. Alternatively or in addition the n-type V-defect generating layer may be or comprise a stack of one or more n-type (Si doped) Alₓ₅Ga₁₋ₓ₅N layers and one or more n-type (Si doped) In_{y2}Ga_{1-y2}N layers. Such a microLED may also comprise a p-type Alₓ₆Ga₁₋ₓ₆ N planarization layer 610 disposed between the active region 415 and the p-type Alₓ₂Ga₁₋ₓ₂N region and filling V-defects in the active region. Ranges for the subscripts defining the compositions of the materials in the n-type V-defect generating layer 605 and the composition of the p-type Alₓ₆Ga₁₋ₓ₆ N planarization layer 610 are provided in the summary section above.

In FIG. 6, two V-defects are depicted as V-shaped deformations in active region 415 centered on threading dislocations 615. V-defects are voids with inverted hexagonal pyramid shapes formed at threading dislocation sites during low-temperature growth, which can later be filled in with high-temperature growth. V-defects provide a lateral path for current flow, minimizing the increase in forward voltage which might otherwise occur with the introduction in active region 415 of high Al-content barriers 420 having large polarization and band offsets with GaN or dilute InGaN wells 425. The physical explanation for preferential lateral current injection through the V-defects is related to a) lower thickness of low-temperature well and barrier layers conformally grown on the inclined planes of the defects and b) reduced interface polarization charges on those planes. When the V-defects are planarized (e.g., with planarization layer 610), there is an additional benefit of lateral carrier confinement away from the threading dislocations, which further improves IQE at low current density vs. the conventional 385 nm LED design.

Typically the density of the V-defects is in the range 10⁸ cm⁻² to 10⁹ cm⁻². The width of the V-defect (referring to width at the top of the feature filled in by planarization layer 610) is typically from 20 nm to 200 nm, however there may be significant size variation between different V-defects even within a single device.

Although devices 400, 500, and 600 shown in FIGS. 4-6 are referred to herein as example microLEDs, they may also be viewed as wafer-sized structures before processing into individually operable microLEDs.

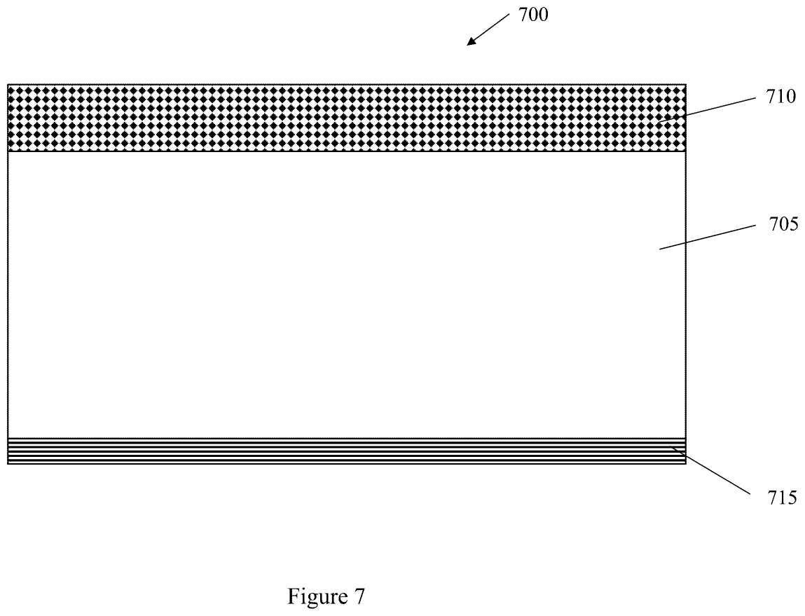

FIG. 7 shows a schematic cross-section of an example wavelength converted microLED 700. MicroLED 700 comprises a near UV microLED structure 705, a layer 710 of quantum dots disposed on a light emitting surface of microLED structure 705, and a mirror 715 disposed on a surface of microLED structure 705 opposite from layer 710 of quantum dots. MicroLED structure 705 can be configured as any of the new near UV microLED structures described above.

In operation, near UV light emitted by microLED structure 705 is converted by quantum dots in layer 710 to visible light, for example to red, green, or blue light. Any suitable quantum dots may be used. It may be advantageous to use Pb and Cd free quantum dots. For example, InP based quantum dots (of different sizes) may be used to convert the near UV light to red or green light, and ZnSe based quantum dots may be used to convert the near UV light to blue light.

For the application of pumping QD color converters, a UV wavelength near 385 nm is considered optimal given several factors: A) Minimizing the optical absorption depth in Cd-free QDs, B) Maximizing the IQE of the (III-nitride based) UV microLED, and C) Minimizing self-absorption of emitted light in non-emitting layers of the LED.

A shorter UV wavelength is desirable for requirement A), while a longer UV wavelength is generally desirable to meet requirements B) and C). In particular, the light extraction efficiency of the LED tends to drop sharply below 390 nm due to absorption in GaN layers which are typically used for dislocation annihilation and n- and p-contact formation. It is possible in principle to replace all those layers with AlGaN, but difficult in practice due to epitaxy strain considerations and the comparatively poor electrical properties of AlGaN layers. The conventional 385 nm-emitting QW typically comprises a thin InGaN layer (with 5% or more In) with GaN barriers or low Al-content AlGaN barriers.

On the other hand, due to the quantum-confined Stark effect, emission wavelengths exceeding the GaN bandgap (365 nm) are possible for indium-free GaN quantum wells with widths exceeding about 3 nm. The red-shift of the emission is the result of a large electric field across the well layer due to AlGaN barrier/GaN well interface polarization charges. For example, a design with 25% Al in the barriers and 3.5 nm GaN well width emits at 385 nm for current densities around 5 A/cm2. The novel GaN and dilute InGaN QW LEDs disclosed herein are estimated to have superior IQE at low current density (FIG. 3), due to the slow recombination lifetime and higher operating carrier density associated with spatial separation of the electron and hole wavefunctions. All recombination rates (including non-radiative recombination) are decreased by the wavefunction separation. The IQE of the novel design is therefore less sensitive to the presence of bulk or surface defects which act as non-radiative recombination centers.

Unlike the conventional InGaN QW LED, the novel GaN and dilute InGaN QW LEDs will exhibit a non-negligible shift of peak wavelength with current density due to changes in the QW internal electric field due to applied forward voltage and screening by free carriers. However, a peak shift in the range up to 10 nm is manageable in the application if the blue QDs absorption edge is broad and has significant absorption even at 395 nm. It should be straightforward to correct for minor changes in the QD absorption when designing displays with current-controlled luminance.

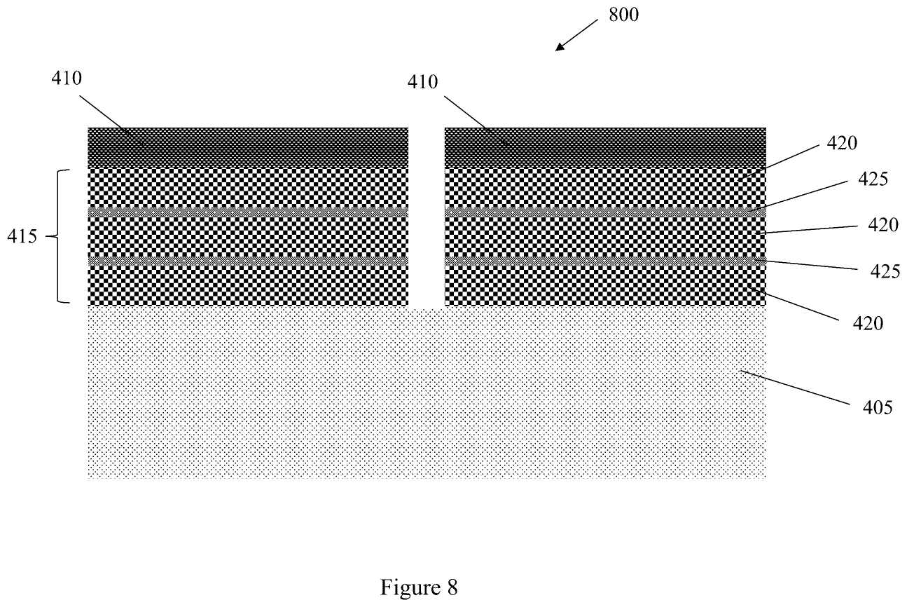

As noted in the summary section, a monolithic array of microLEDs may comprise two or more of any of the novel microLED structures described above physically interconnected by a shared n-type Alₓ₁Ga₁₋ₓ₁N region. FIG. 8 shows a schematic cross-section of a portion 800 of an example of such a monolithic array of microLEDs, with two microLEDs sharing n-type Alₓ₁Ga₁₋ₓ₁N region 405. The trench separating the two microLEDs shown in this Figure may be filled, for example, with optical isolation material and/or electrical contacts to the p-side of the devices.

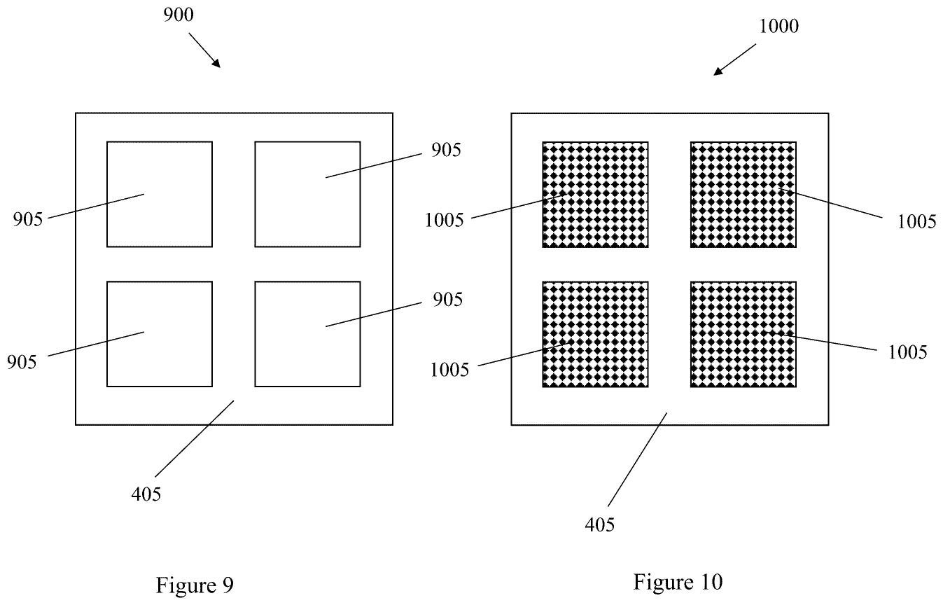

FIG. 9 shows a plan view of an example monolithic array 900 of novel near UV direct-emitting microLEDs 405 as disclosed herein. FIG. 10 similarly shows a plan view of an example monolithic array 1000 of quantum dot wavelength converted microLEDs 1005 as disclosed herein.

Although FIGS. 8, 9, and 10 show monolithic arrays of only two or four microLEDs, such a monolithic array may comprise any suitable number of microLEDs.

Novel near UV microLED arrays as disclosed herein may be used for example in displays (with QD color conversion, as discussed above). Another application is in 3D printing (for example, to cure the printed material). The use of a UV microLED array for 3D printing may have advantages in energy efficiency vs. the existing approach of reflecting the emission of a large UV LED from an array of liquid-crystal-on silicon (LCOS) mirrors.

This disclosure is illustrative and not limiting. Further modifications will be apparent to one skilled in the art in light of this disclosure and are intended to fall within the scope of the appended claims.

What is claimed is:

1. A microLED comprising:
an n-type Alₓ₁Ga₁₋ₓ₁N region, 0≤x1≤0.6;
a p-type Alₓ₂Ga₁₋ₓ₂N region, 0≤x2≤0.6; and
an active region disposed between the n-type Alₓ₁Ga₁₋ₓ₁N region and the p-type Alₓ₂Ga₁₋ₓ₂N region, the active region comprising:
two or more Alₓ₃Ga₁₋ₓ₃N barrier layers, 0.10≤x3≤1.0, each Alₓ₃Ga₁₋ₓ₃N barrier layer having a thickness perpendicular to the layer of about 5.0 nm to about 20 nm; and
one or more In_{y}Ga_{1-y}N quantum well layers, 0.0≤y<0.05, each In_{y}Ga_{1-y}N quantum well layer having a thickness of about 3.0 nm to about 6.0 nm and disposed between a pair of adjacent Alₓ₃Ga₁₋ₓ₃N barrier layers.

2. The microLED of claim 1, wherein the active region has a largest dimension of less than or equal to about 50 microns parallel to the barrier layers and the quantum well layers.

3. The microLED of claim 2, wherein the active region has a largest dimension of less than or equal to about 20 microns parallel to the barrier layers and the quantum well layers.

4. The microLED of claim 3, wherein the active region has a largest dimension of less than or equal to about 5 microns parallel to the barrier layers and the quantum well layers.

5. The microLED of claim 1, configured to emit light having a peak wavelength of about 375 nm to about 395 nm upon application of a forward bias across the active region.

6. The microLED of claim 5, configured to emit light having a peak wavelength of about 385 nm upon application of a forward bias across the active region.

7. The microLED of claim 1, wherein 0.10≤x3≤0.50.

8. The microLED of claim 1, wherein 0.0≤y≤0.02.

9. The microLED of claim 1, wherein:
the active region has a largest dimension of about less than or equal to about 20 microns parallel to the barrier layers and the quantum well layers;
0.10≤x3≤0.50; and
0.0≤y≤0.02.

10. The microLED of claim 9, wherein:
x3=0.25; and
y=0.0.

11. The microLED of claim 9, configured to emit light having a peak wavelength of about 375 nm to about 395 nm upon application of a forward bias across the active region.

12. The microLED of claim 1, comprising an n-type V-defect generating layer disposed between the n-type Alₓ₁Ga₁₋ₓ₁N region and the active region and generating V-defects in the active region.

13. The microLED of claim 12, wherein the n-type V-defect generating layer is or comprises an n-type Alₓ₄Ga₁₋ₓ₄N layer, 0≤x4≤0.5.

14. The microLED of claim 12, wherein the n-type V-defect generating layer is or comprises a stack of one or more Alₓ₅Ga₁₋ₓ₅N layers and one or more In_{y2}Ga_{1-y2}N layers, 0≤x5≤0.15, 0.0≤y2≤0.85.

15. The microLED of claim 12, comprising a p-type Alₓ₆Ga₁₋ₓ₆N planarization layer disposed between the active region and the p-type Alₓ₂Ga₁₋ₓ₂N region and filling V-defects in the active region, 0.10≤x6≤0.4.

16. The microLED of claim 15, wherein:
the active region has a largest dimension of less than or equal to about 20 microns parallel to the barrier layers and the quantum well layers;
x3=0.25;
y=0.0; and
x6=0.10.

17. The microLED of claim 5, comprising quantum dots arranged and configured to absorb ultraviolet light emitted by the active region and in response emit visible light.

18. A monolithic array comprising two or more microLEDs as in claim 1 physically interconnected by a shared n-type Alₓ₁Ga₁₋ₓ₁N region.

19. The monolithic array of microLEDs of claim 18, each microLED configured to emit light having a peak wavelength of about 375 nm to about 395 nm upon application of a forward bias across the microLED's active region.

20. The monolithic array of microLEDs of claim 19, comprising quantum dots arranged and configured to absorb ultraviolet light emitted by the active regions of the microLEDs and in response emit visible light, wherein the quantum dots comprise red-emitting, blue-emitting, and green-emitting quantum dots arranged with respect to the microLEDs to form red, blue, and green microLED pixel elements.
